(19) United States
(12) Patent Application Publication
(10) Pub. No.: US 2009/0124085 A1
(43) Pub. Date: May 14, 2009

(54) METHOD FOR FORMING A SEMICONDUCTOR DEVICE HAS A LENGTHENED CHANNEL LENGTH

(75) Inventors: Hung-Ming TSAI, Kaohsiung City (TW); Ying Cheng CHUANG, Taoyuan (TW)

Correspondence Address: INGRASSIA FISHER & LORENZ, P.C., 7010 E. COCHISE ROAD, SCOTTSDALE, AZ, 85253, US

(73) Assignee: NANYA TECHNOLOGY CORP., Taoyuan (TW)

(21) Appl. No.: 12/019,178

(22) Filed: Jan. 24, 2008

(30) Foreign Application Priority Data
Nov. 14, 2007 (TW) 96142982

(51) Int. Cl. H01L 21/311

(52) U.S. Cl. 438/702; 257/E21.249

(57) ABSTRACT

The present invention discloses a method for forming a semiconductor device. The method includes providing a substrate; forming at least one first opening in the substrate to a predetermined depth and exposing a sidewall of the substrate in the first opening; forming a spacer on the sidewall and exposing a portion of the substrate in the bottom of the first opening; etching the exposed substrate in the bottom of the first opening by using the spacer as a mask to form a second opening; forming an isolation layer in the second opening and a portion of the first opening; forming a gate dielectric layer on the surface of the substrate; and forming a conductive layer covering the substrate.

### CROSS REFERENCE TO RELATED APPLICATIONS

This application claims priority of Taiwan Patent Application Serial No. 096142982 entitled “Method for Forming Semiconductor Device”, filed Nov. 14, 2007.

### FIELD OF THE INVENTION

The present invention relates to a method for forming a semiconductor device, and more particularly, to a method for forming a semiconductor device to reduce the inverse narrow width effect.

### BACKGROUND OF THE INVENTION

Recently, the semiconductor technology develops rapidly while manufacturing the semiconductor devices requires more and more demands and quality controls. As the critical dimension of the device continuously shrinks, more and more devices can be manufactured in a given area to significantly enhance the performance of the semiconductor device. However, many difficulties simultaneously emerge while the size of device becomes smaller.

In an active area of a semiconductor device, for example, the reduction of effective channel width in the gate oxide causes an inverse narrow width effect (INWE) in the width direction of the gate. The inverse narrow width effect significantly interferes the normal operation of the semiconductor device.

Therefore, it is advantageous to have a method for reducing the inverse narrow width effect of the semiconductor device.

### SUMMARY OF THE INVENTION

The present invention discloses a method for forming a semiconductor device, including: providing a substrate; forming at least one first opening in the substrate to a predetermined depth to expose a sidewall of the substrate in the first opening; forming a spacer on the sidewall to expose a portion of the substrate in the bottom of the first opening; etching the exposed substrate in the bottom of the first opening by using the spacer as a mask to form a second opening; forming an isolation layer in the second opening and a portion of the first opening; removing the spacer to form a recess; forming a gate dielectric layer on the surface of the substrate; and forming a conductive layer covering the substrate.

In another aspect of the present invention, the substrate includes a silicon substrate, a pad oxide layer and a pad nitride layer, and the step of removing the spacer further includes removing the pad nitride layer and the pad oxide layer.

In a further another aspect of the present invention, the step of forming the first opening includes: forming a patterned photoresist layer on the substrate, the patterned photoresist layer defining at least one gate area and the at least one first opening; etching the substrate to the predetermined depth by using the patterned photoresist layer as a mask; and removing the patterned photoresist layer.

In yet another aspect of the present invention, the recess is located between the isolation layer and the substrate in the gate area, and the step of forming the gate dielectric layer includes forming the gate dielectric layer on a substrate surface in the gate area and a substrate surface exposed in the recess.

In still another aspect of the present invention, the gate dielectric layer within the recess presents an L-shape.

In further still another aspect of the present invention, the step of forming the spacer includes: forming a conformal dielectric layer covering the substrate; and anisotropically etching the conformal dielectric layer to form the spacer.

In yet another aspect of the present invention, the step of forming the isolation layer includes: forming an insulating layer covering the substrate and filling the first opening and the second opening; and etching the insulating layer to form the isolation layer.

The above and further objectives, advantages and novel features will be best understood by the following illustrative embodiments with reference to the detail descriptions in conjunction with the accompanying drawings.

### BRIEF DESCRIPTION OF THE DRAWINGS

FIG. 1 is a cross-sectional view in accordance with one embodiment of the present invention to illustrate the step of providing a substrate for the method of forming the semiconductor device;

FIG. 2 is a cross-sectional view in accordance with one embodiment of the present invention to illustrate the step of forming the patterned photoresist layer for the method of forming the semiconductor device;

FIG. 3 is a cross-sectional view in accordance with one embodiment of the present invention to illustrate the step of forming the first opening for the method of forming the semiconductor device;

FIG. 4 is a cross-sectional view in accordance with one embodiment of the present invention to illustrate the step of forming the spacer for the method of forming the semiconductor device;

FIG. 5 is a cross-sectional view in accordance with one embodiment of the present invention to illustrate the step of forming the second opening for the method of forming the semiconductor device;

FIG. 6 is a cross-sectional view in accordance with one embodiment of the present invention to illustrate the step of forming the insulating layer for the method of forming the semiconductor device;

FIG. 7 is a cross-sectional view in accordance with one embodiment of the present invention to illustrate the step of forming the isolation layer for the method of forming the semiconductor device;

FIG. 8 is a cross-sectional view in accordance with one embodiment of the present invention to illustrate the step of forming the recess for the method of forming the semiconductor device; and

FIG. 9 is a cross-sectional view in accordance with one embodiment of the present invention to illustrate the step of forming the gate dielectric layer and the conductive layer for the method of forming the semiconductor device.

### DETAILED DESCRIPTION

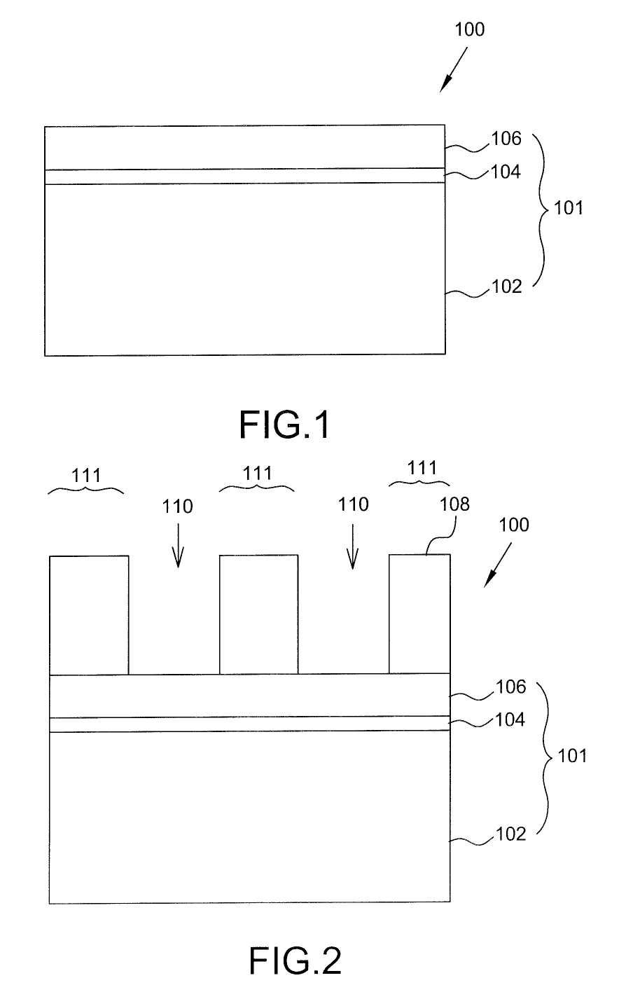

The present invention discloses a method for forming a semiconductor device to reduce the inverse narrow width effect (INWE) and increase the effective channel width to raise the source current (IDS), thus the performance of the semiconductor device is maintained while the size of the device becomes even smaller. First, a substrate 101, including a silicon substrate 102, a pad oxide layer 104 and a pad nitride layer 106, is provided as shown in FIG. 1. It is noted that the drawings are not necessarily drawn to scale in order to provide better understanding to the present invention. Also, those who skilled in the art may understand that there may be other components or devices on the substrate, even they are not shown in the drawings for conciseness considerations. Therefore, the scope of the present invention are not limited to any particular embodiment hereinafter.

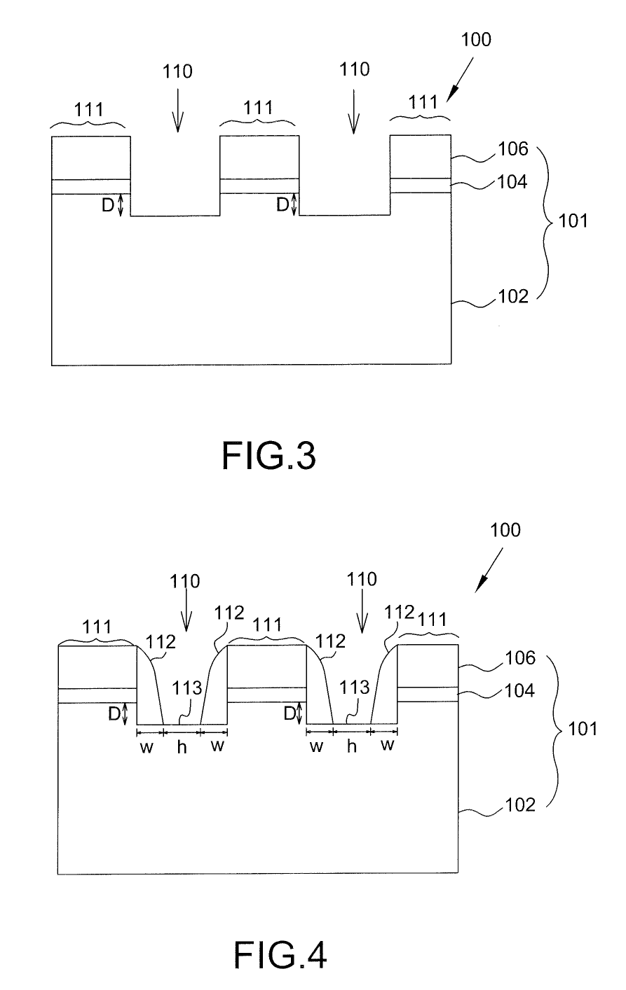

Further referring to FIG. 2, a patterned photoresist layer 108 is formed on the substrate 101, and the patterned photoresist layer 108 defines at least one gate area 111 and at least one first opening 110. In this embodiment, the semiconductor device 100 is a memory device, and the area defined by the first opening 110 is the isolation area, that is, the cross-sectional direction is the width direction of the gate. The substrate 101 exposed in the defined first opening 110 is etched, including the pad nitride layer 106, pad oxide layer 104 and silicon substrate 102, to a predetermined depth D in the silicon substrate 102 by using the patterned photoresist layer 108 as a mask. The predetermined depth D may be determined case-by-case depending on specific electrical characteristics of a specific device. Thereafter, the patterned photoresist layer 108 is removed as shown in FIG. 3.

Please refer to FIG. 4. The first opening 110 in the substrate 101 exposes a sidewall of the substrate 101. A spacer 112 is then formed on the inner sidewall of the first opening 110 while leaves a bottom face of the first opening 110 partially exposed. The spacer 112 may be formed by forming a conformal dielectric layer (not shown) to cover the substrate 101 and then partially removed by anisotropically etching. In one embodiment, for example, boron-silicate (BSG) may be used to form a BSG spacer. The width of the spacer 112 may be precisely controlled to a predetermined width w by means of the etching process of the conformal dielectric layer. Thus, the width h of the exposed bottom of the first opening 110 may also be controlled to a desired width.

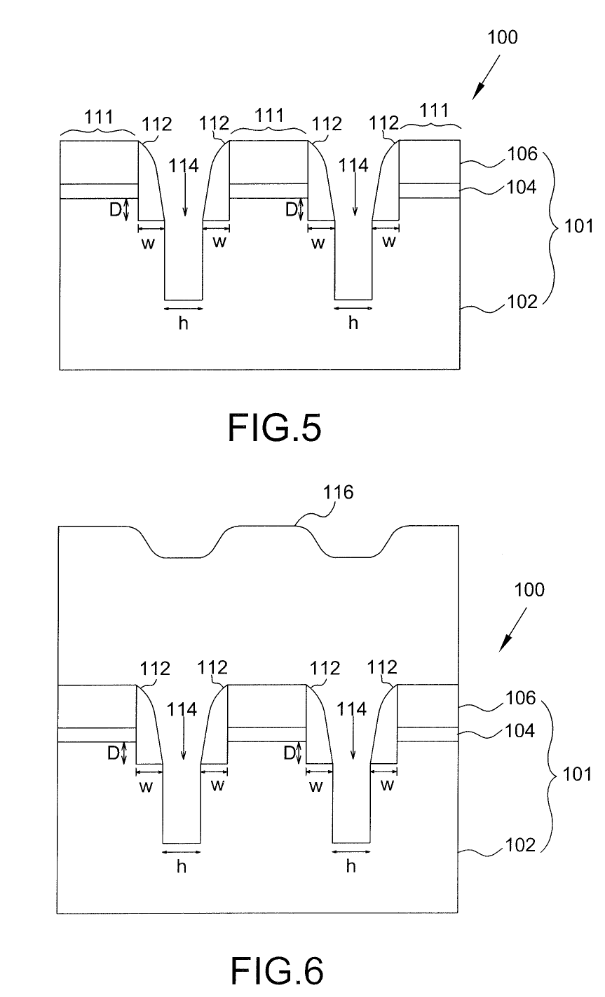

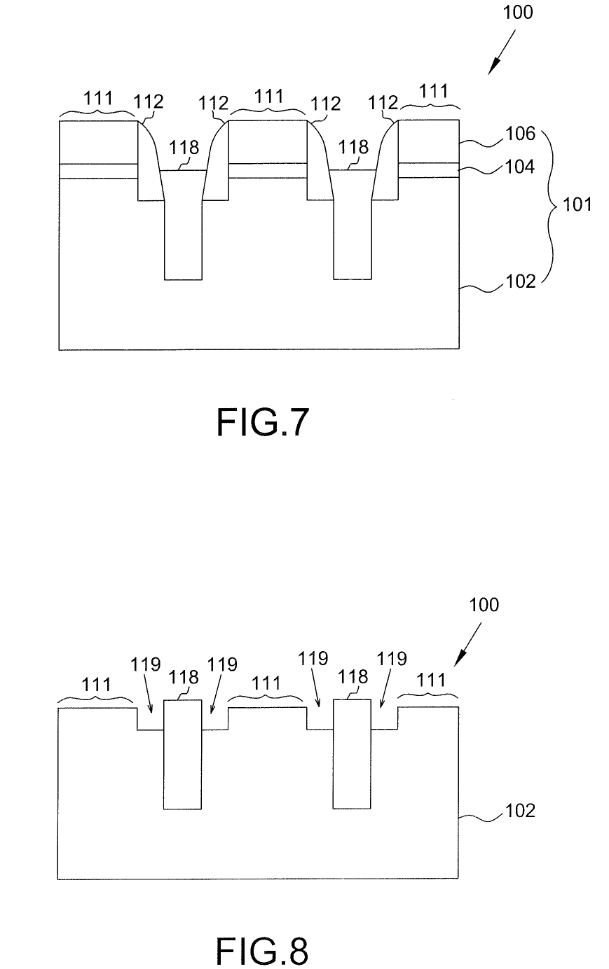

Further referring to FIG. 5, the exposed portion of the first opening 110 is etched by using the spacer 112 as a mask to form a second opening 114. An insulating layer 116 is then formed to cover the substrate 101 and filled into the first opening 112 and the second opening 114 by using a deposition process, such as high density plasma chemical vapor deposition. Thereafter, the insulating layer 116 is etched to form the isolation layer 118 as shown in FIG. 7. The isolation layer 118 fills the second opening 114 and a portion of the first opening 110. In this embodiment, for example but not limited to, the insulating layer 116 is etched back to a level proximal to the level of the pad oxide layer 104 in the first opening 110. The isolation layer 118 is used as the isolation between gates of the semiconductor devices 100. The width h is controlled by the predetermined width w as described in the above step, thus the width h may be easily adjusted to a desired value, at least larger than a minimum value, to maintain the isolation effect.

The spacer 112 is then removed to form a recess 119. Further, the pad nitride layer 106 and the pad oxide layer 104 are removed by using such as wet etching process. The recess 119 is located between the isolation layer 118 and the silicon substrate 102 in the gate area 111 as shown in FIG. 8.

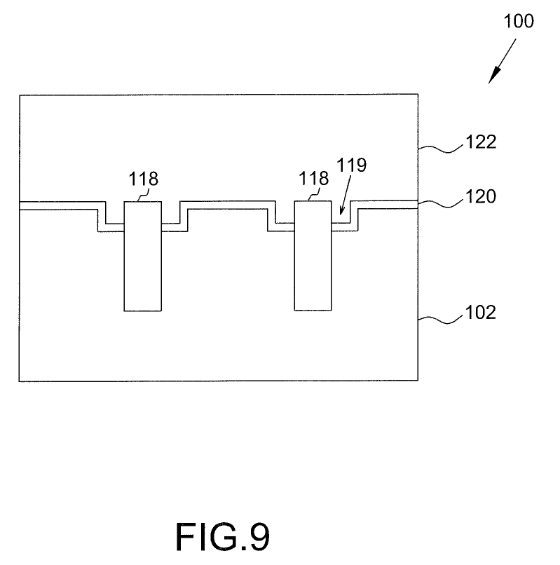

A gate dielectric layer 120, such as an oxide layer, is formed on the surface of the silicon substrate 102, particularly on a substrate surface in the gate area 111 and a substrate surface exposed in the recess 119. The gate dielectric layer 120 may be formed by a thermal oxidation process. The gate dielectric layer 120 within the recess 119 presents an L-shape as shown in FIG. 9. A conductive layer 112 is then formed to cover the silicon substrate 102 as word lines of the memory device in this embodiment.

By means of the method described above, the gate dielectric layer 120 of the semiconductor device 100 could be extended to the recess 119, that is, the L-shape portion of the gate dielectric layer 120. Moreover, the gate dielectric layer 120 extends a total length of depth D and width w comparing to the traditional process, which in turns increasing the effective channel width of the semiconductor device 100. Therefore, the present invention provides a novel process for reducing the inverse narrow width effect and improving the performance of the semiconductor device 100.

The above description only sets forth preferred embodiment of the invention, and is not intended to limit the scope, applicability, or configuration of the invention in any way. Rather, various changes may be made in the function and arrangement of the elements described in the embodiment without departing from the spirit and scope of the invention. Thus, the protected scope of the present invention is as set forth in the appended claims.

What is claimed is:

1. A method for forming a semiconductor device, comprising:
providing a substrate;
forming at least one first opening in the substrate to a predetermined depth to expose a sidewall of the substrate in the first opening;
forming a spacer on the sidewall to expose a portion of the substrate in the bottom of the first opening;
etching the exposed substrate in the bottom of the first opening to form a second opening in the substrate;
filling an isolation layer in the second opening and a portion of the first opening;
removing the spacer to form a recess to partially expose the substrate;
forming a gate dielectric layer on the surface of the substrate; and
forming a conductive layer covering the substrate so that the semiconductor device has a lengthened channel length due to existence of the recess.

2. The method for forming the semiconductor device according to claim 1, wherein the substrate comprises a silicon substrate, a pad oxide layer and a pad nitride layer, and the step of removing the spacer further comprises removing the pad nitride layer and the pad oxide layer.

3. The method for forming the semiconductor device according to claim 2, wherein the step of forming the first opening comprises:
forming a patterned photoresist layer on the substrate, the patterned photoresist layer defining at least one gate area and the at least one first opening;
etching the substrate to the predetermined depth; and
removing the patterned photoresist layer.

4. The method for forming the semiconductor device according to claim 3, wherein the recess is located between the isolation layer and the substrate in the gate area, and the step of forming the gate dielectric layer comprises forming the gate dielectric layer on a substrate surface in the gate area and a substrate surface exposed in the recess.

5. The method for forming the semiconductor device according to claim 4, wherein the gate dielectric layer within the recess presents an L-shape.

6. The method for forming the semiconductor device according to claim 1, wherein the step of forming the spacer comprises:
forming a conformal dielectric layer covering the substrate; and
anisotropically etching the conformal dielectric layer to form the spacer.

7. The method for forming the semiconductor device according to claim 1, wherein the step of forming the isolation layer comprises:
forming an insulating layer covering the substrate and filling the first opening and the second opening; and
etching the insulating layer to form the isolation layer.
